(19) United States
(12) Patent Application Publication
(10) Pub. No.: US 2013/0217237 A1
(43) Pub. Date: Aug. 22, 2013

(54) SPIN-ON DIELECTRIC METHOD WITH MULTI-STAGE RAMPING TEMPERATURE

(71) Applicants: Kuen-Shin HUANG, New Taipei City (TW); Chiuan-Heng DU, Taipei City (TW); Yao-Jen CHANG, Taoyuan County (TW); Yau Ying TZENG, Taoyuan County (TW); Ming-Tai CHIEN, New Taipei City (TW); Chun-Yu LEE, New Taipei City (TW)

(72) Inventors: Kuen-Shin HUANG, New Taipei City (TW); Chiuan-Heng DU, Taipei City (TW); Yao-Jen CHANG, Taoyuan County (TW); Yau Ying TZENG, Taoyuan County (TW); Ming-Tai CHIEN, New Taipei City (TW); Chun-Yu LEE, New Taipei City (TW)

(73) Assignee: INOTERA MEMORIES, INC., Taoyuan County (TW)

(21) Appl. No.: 13/457,765

(22) Filed: Apr. 27, 2012

(30) Foreign Application Priority Data
Feb. 17, 2012 (TW) 101105239

(51) Int. Cl. H01L 21/312

(52) U.S. Cl. 438/761; 257/E21.259; 438/781

(57) ABSTRACT

A Spin-On Dielectric (SOD) method with multi stage ramping temperature for coating a dielectric material onto a substrate, comprising the steps of: (a) placing the substrate on a chill plate to decrease the temperature; (b) fixing the chilled substrate on a spinning device; (c) rotating the spinning device to drive the substrate rotating; (d) injecting the dielectric material onto the center of the substrate; (e) spreading the dielectric material on the upper surface of the substrate by spinning; (f) baking the substrate and the dielectric material by a heat plate to achieve multi stages ramping temperature, where the temperature of each stage has a steady state temperature for a predetermined time and the posterior stage has higher temperature than the anterior stage; (g) placing the substrate on the chill plate for cooling down; (h) spreading a film of dielectric material and finishing the coating.

### BACKGROUND OF THE INVENTION

1. Field of the Invention

The present invention relates to a Spin-On Dielectric (SOD) method, particularly to a SOD method with multi stage ramping temperature for manufacturing semiconductors.

2. Description of Related Art

Along with the development of the Integrated Circuit (IC) technology, the dimension of the electrical components has been minimized to sub-micrometer; this also leads to faster component processing speed and higher component density. Under extremely shrinkage of the component size, the electric component with single layout deposited cannot sufficiently sustain their connection and arrangement. In this manner, many electrical components integrated within a single semiconductor IC introduce wiring delay noticeably. This is because the larger the number of devices integrated, the larger line-to-line capacitance it may have (i.e., parasitic capacitance between metal interconnects), thus interfering with the performance improvement of a semiconductor integrated circuit. The wiring delay is so-called “RC delay”, which is proportional to the product of the resistance of metal interconnection and the line-to-line capacitance. Practically, the complex structure and extremely tiny size component is the factor which leads to RC delay in transmission rate.

In this manner, the multi layout disposition having extremely tiny component with interconnect wire inside is absolutely required to meet the need. However, more complex and multi layout disposition usually result in higher cost and more manufacturing hurdle, and then eventually bring to the lower product yield. In order to settle these problem, the copper wire with lower resistance (i.e. k<2.0) is utilized, particularly applied in 0.25 μm width of manufacture, to substitute traditional aluminum/silicon dioxide wire of manufacture.

Nowadays, multi layout wire structure made of low resistance copper and equipped with low dielectric film had been commonly utilized in 0.18 μm width of IC or semiconductor manufacture for years. In addition, new material is sometimes introduced to the wire structure of semiconductor fabrication in order to reduce the power consumption during energy transmission and the interference among cross-wires. However, new material introduced normally has some other new manufacturing problems, e.g. trendless for copper wire etching or tendency for diffusing in silicon oxide; this might change the physical properties of the electrical component in bottom side. In comparison to the metal etching process or dielectric film deposition manufacturing, traditional manufacturing method, e.g. Damascene process, discloses that the copper wire/low dielectric constant film may be applied in the multi layout wire structure. The prior art method normally contains dry etching and cleaning for low dielectric constant film, copper sputtering and filling for diffusion barrier, copper crystal electroplating, Chemical Mechanical Polishing (CMP), etc. The benefit of such copper wire manufacture is definitely that acceptable lower interconnect RC delay due to lower dielectric constant material is applied.

The relative tech and process regarding to the copper chip fabrication had been disclosed in the fall of 1997 by IBM and Motorola, to drastically reduce the RC delay of electrical signal transmission in the chip with sub-micrometer width; furthermore, the disclosed method may also have better electro-migration resistance and improve reliability for high current density generated from extremely shrinking size. In this method, lower dielectric constant than SiO₂ (i.e. k˜2) is utilized in the dielectric layer, to settle the problem of RC delay, energy consumption, and cross-talk noise between wires. However, the process for conquering the hurdle of low dielectric material is still higher than traditional aluminum alloy process. In this reason, it is indeed practical to take the manufacturing cost into account and utilize the copper wire process, rather than settling the problem of the low dielectric material process.

Conventionally, the deposition process may utilize the Spin-On Dielectric (SOD) or Chemical Vapor Deposition (CVD) fabrication. The SOD may have advantage of easily achieved and uniform spread by modifying the solvent of styrene (also call “DBE”) contained, and flowing the dielectric material on the porous substrate. In this manner, the SOD process is able to be easily fulfilled, to have k˜2.0 of semiconductor product. The SOD process is mainstream and commonly utilized in the semiconductor industry for years because the dielectric constant can be limited below k˜2 by means of porous substrate. Some other process cannot have such merit rather than SOD process.

To be detailed, the SOD process may arrange a plurality of trenches with different width, different length, different profile, and even different shape on the upper surface of the substrate. After the dielectric material is spread and the SOD process is finished, the dielectric film eventually covers the uneven upper surface of the substrate. In this manner, some cavity (so-called “Void” defect) may usually exist between the concave sites. In actual process, the Void defect is normally found inside the trench, and therefore the position of the Void defect is located at slightly upper of middle trench. In this manner, the DBE cannot be properly removed and then the residue of solvent compound is too high, so as to prevent the formation of oxide film. Then the formed oxide film may not have enough mechanical strength. Namely, once it has less solvent removed out or higher residue remained in the bottom side, the worse quality of SiO₂ film (less strength) through the high temperature conversion process was normally occurred. In addition, there are some drawbacks cannot be resolved currently, e.g. the product reliability issue regarding to the SOD method being more complicated than CVD method, the solvent residue been uneasily removed, significant shrinkage of film thickness existed in solidification or polymerization, the mechanical stress usually generated, fluctuating dielectric constant produced, and cracking phenomenon occurred after solidification, etc.

In this reason, how to improve the shrinkage of film thickness existed in solidification or polymerization, to diminish the Void generated under SOD film, and to reduce the residue solvent compound so as to increase the generation of the silicon oxide and improve its mechanical strength, is the problem need to be settled.

### SUMMARY OF THE INVENTION

The primary object of the present invention is to improve the shrinkage of film thickness existed in solidification or polymerization, and to diminish the Void defect occurred under SOD film.

Another object of the present invention is to reduce the residue solvent compound under the SOD film, so as to ensure a better mechanical strength of the silicon oxide film and its generation with high quality product yield.

To achieve the foregoing and the other objects, a Spin-On Dielectric (SOD) method with multi stage ramping temperature for coating a dielectric material onto a substrate is disclosed. The SOD method comprising the step: (a) placing the substrate on a chill plate to decrease the temperature; (b) fixing the chilled substrate on a spinning device; (c) turn on the spinning device to rotate the substrate; (d) injecting a dielectric material onto the center of the substrate; (e) coating the dielectric material on the upper surface of the substrate by spinning motion; (f) baking the substrate and the dielectric material by a heat plate to achieve multi stages ramping temperature, where the temperature of each stage has a steady state maintained for a predetermined time and the posterior stage has higher temperature than the anterior stage; (g) placing the substrate on the chill plate for cooling down; (h) spreading a film of dielectric material and finishing the coating.

In the aforementioned SOD method with multi stage ramping temperature, the dielectric material is polystyrene or polysilazane, and average molecular weight of the dielectric material is 1,200˜20,000.

In the aforementioned SOD method with multi stage ramping temperature, the upper surface of the substrate has at least one trench having a width smaller than or equal to 0.2 μm, and aspect ratio greater than or equal to 2.

In the aforementioned SOD method with multi stage ramping temperature, the step (f) has 2˜6 stages, and the temperature of each stage is kept in constant; the temperatures of two adjacent stages define a temperature difference, and the temperature differences between all stages are equal or unequal. Preferably, the step (f) has three heating stages. For the first heating stage, the substrate and the dielectric material are heated under a temperature of 90° C.+/−10%. For the second heating stage, the substrate and the dielectric material are heated under a temperature of 120° C.+/−10%. Whereas for the third heating stage, the substrate and the dielectric material are heated under a temperature of 150° C.+/−10%.

In the aforementioned SOD method with multi stage ramping temperature, wherein the step (f) has 2˜6 stages, and the temperature of each stage is variant; each stage increases the temperature by constant rate heating until the steady state.

In the aforementioned SOD method with multi stage ramping temperature, wherein total time of step (f) for heating is 3˜6 minutes.

Based on the above described steps, the solvent inside the dielectric material is readily reacted and evaporated. The quality of the deposited film is free from the effect of the solvent residue. Thus, polysilazane (dielectric material) has enough time to react in forming an oxide layer of silicon dioxide (SiO₂) during the oxidation stage. Moreover, voids are less likely to occur in the deposited film, where the deposited film has a higher mechanical strength.

In order to further appreciate the characteristics and technical contents of the instant disclosure, references are hereunder made to the detailed descriptions and appended drawings in connection with the instant disclosure. However, the appended drawings are merely shown for exemplary purposes, rather than being used to restrict the scope of the instant disclosure.

### BRIEF DESCRIPTION OF THE DRAWINGS

FIG. 1A shows the flow chart of the Spin-On Dielectric (SOD) method with multi stage ramping temperature according to the present invention;

FIG. 1B shows the flow chart of one embodiment of the step S6 regarding to the multi stage heating process;

FIGS. 2A˜2D show the devices for the SOD method of the present invention;

FIG. 3A is “constant temperature” heating diagram of the step S6;

FIG. 3B is “variant temperature” heating diagram of the step S6;

FIGS. 4A˜4B show the quality of the SOD method of the present invention.

### DETAILED DESCRIPTION OF PREFERRED EMBODIMENT

The semiconductor technology has been developed and improved for decades, so that it may drive the computer science, tele-communication and the internet industries to grow quickly. The factor for this improvement might partially because of the gradually shrunk size of the electrical component. The size reduction enables higher component density, lower power consumption, and speedy signal transmission as well as better function and higher performance (e.g. message storage, logic/algorism calculation, and information dealing with, etc.). Under the trend of minimization, the Spin-On Dielectric (SOD) process is normally utilized for electrical component and chip fabrication, so as to coat and deposit the material with low dielectric constant (i.e. k<10.0) on the surface of the chip or electrical component.

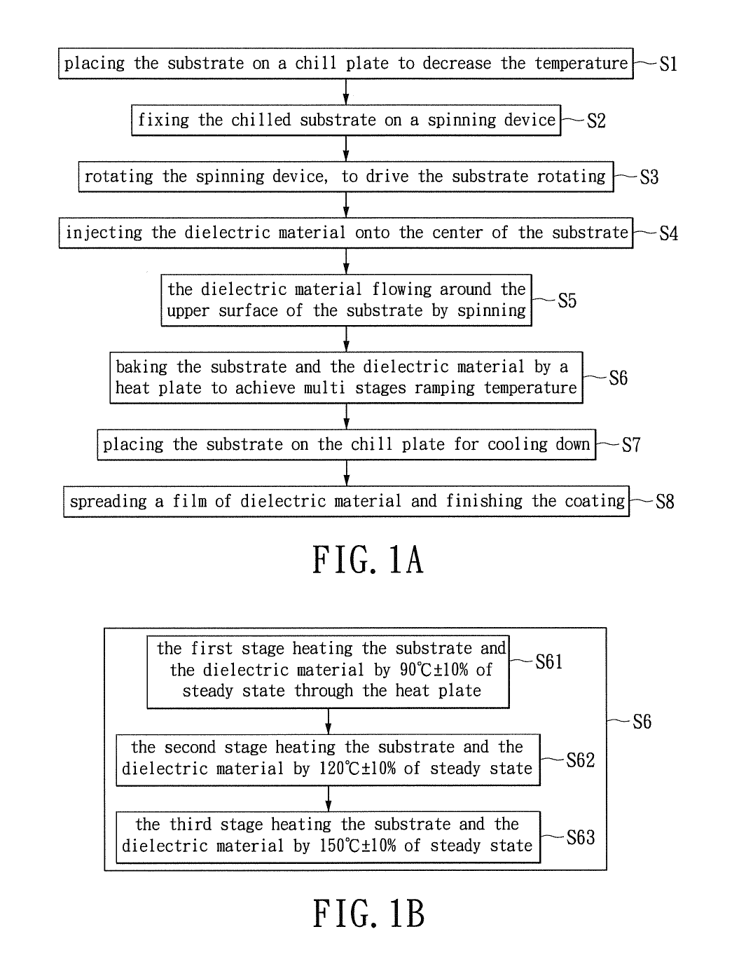

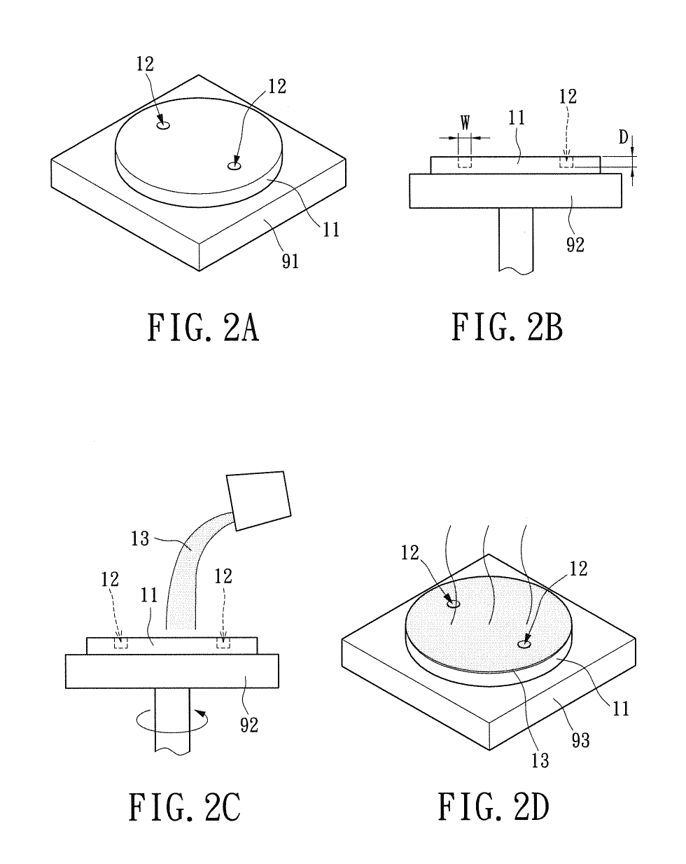

Please refer to FIG. 1 and FIGS. 2A˜2D, the Spin-On Dielectric (SOD) method of the present invention may be utilized for processing a substrate 11. The substrate 11 may be semiconductor material or electroplating material. In practice, a plurality of trenches 12 is pre-formed on the upper surface of the substrate 11. After repeated experiments, it is shown that a substrate having a width W of the trench 12 smaller than or equal to 0.2 nm and the aspect ratio (the value of depth D divided by width W) greater than or equal to 2 is best suited for applying the SOD method.

After the substrate 11 has undergone the pre-treatment process, the substrate 11 is at a high temperature. Then, as shown in FIG. 2A, the substrate 11 is placed on a chill plate 91 to decrease the temperature (Step S1). Preferably, the temperature decreasing rate through the chill plate 91 is 22˜24° C. every minute. Afterward as shown in FIG. 2B, the chilled substrate 91 is fixed on a spinning device 92 (Step S2), and the spinning device 92 is turned on to spin the substrate 11 (Step S3). Normally, the spinning device 92 is commonly called as “spin coater”. As shown in FIG. 2C, a dielectric material 13 is injected centrally onto the upper surface of the substrate 11 (Step S4), therefore the dielectric material 13 is flowed around the upper surface of the substrate 11 by spinning (Step S5). More specifically, a specific precursor is dissolved in a chemical solvent to form the dielectric material 13 in the form of a chemical solution (i.e. liquid phase); then the liquid dielectric material 13 is dropped on the rotating substrate 11. In this manner, the solution of the dielectric material 13 on the substrate 11 is able to be uniformly flowed and spread to cover the entire surface of the substrate 11 by means of centrifugal force to complete the film coating operation. Typically, the dielectric material 13 of liquid phase is polystyrene solution or polysilazane solution, which has an average molecular weight ranging approximately from 1,200 to 20,000.

After the dielectric material 13 is spread uniformly on the substrate 11, the substrate 11 and the dielectric material 13 are baked (i.e. heated to increase the temperature) by a heat plate 93 to achieve multi stages ramping temperature (Step S6) as shown in FIG. 2D. The multi stage ramping temperature can bake and heat the dielectric material 13, and transform the polysilazane into silicon oxide (SiO₂). In this step, the temperature of each stage is maintained at a steady state for a predetermined time, and the posterior stage has higher temperature than the anterior stage. Preferably, step S6 has 2˜6 stages, and the temperature of each stage may be increasing continuously or kept constant.

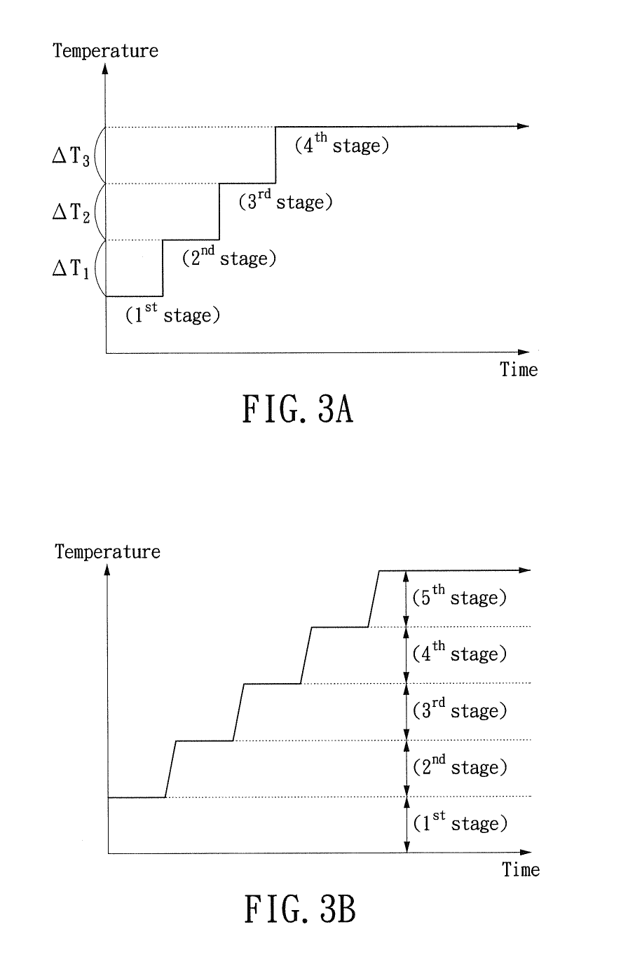

As shown in FIG. 3A, the multi stage heating process is defined by different stages to increase the temperature of the dielectric material 13, in which each stage has a constant steady state temperature. In FIG. 3A, four heating stages are shown. A temperature difference such as ΔT₁, ΔT₂, and ΔT₃ exists between adjacent heating stages, where ΔT₁=ΔT₂=ΔT₃.

Alternatively, as shown in FIG. 3B, each of the five heating stages is defined by the substrate 11 being heated at a constant rate over a period of time. Preferably, each heating stage increases the temperature by a constant rate to a threshold temperature (i.e., the temperature slope of each heating stage is the same). Typically, a constant-rate heating procedure is easier to manage during the manufacturing process.

Moreover, based on experiments, it is discovered that the total heating time of step S6 is preferably in the range of 3˜6 minutes, regardless of constant temperature heating or non-constant temperature heating.

Moreover, some experimental data is disclosed herein to better explain the multi stage heating process of the present invention. As shown in FIG. 1B, for Step S6, the heat plate 93 is utilized to perform a three-stage heating process. For the first stage, at a constant temperature, the substrate 11 and the dielectric material 13 are heated at 90° C.±10% (Step S61). Then, the second stage heats the substrate 11 and the dielectric material 13 at a constant temperature of 120° C.±10% (Step S62). Finally, the third stage heats the substrate 11 and the dielectric material 13 at a constant temperature of 150° C.±10% (Step S63). The temperature difference between the first stage and the second stage is 30° C. (i.e. 120−90=30° C.); the temperature difference between the second stage and the third stage is also 30° C. (i.e. 150−120=30° C.). Therefore, the temperature differences ΔT between adjacent stages are the same.

After the multi stage heating process is completed, the substrate 11 is placed again on the chill plate 91 for cooling down (Step S7). After the temperatures of the substrate 11 and the dielectric material 13 have reached the room temperature, the spreading and coating of a film of dielectric material is completed (Step S8).

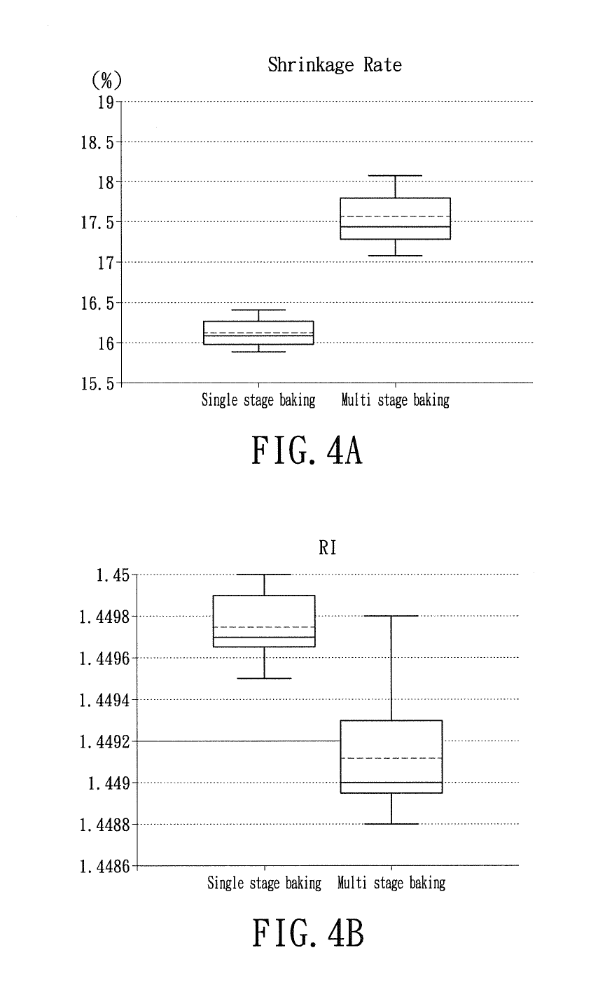

According to the SOD method with multi stage ramping temperature for coating the dielectric material 13 onto the substrate 11, the solvent compound among the dielectric material 13 may be fully reacted and evaporated without remaining inside the product film. In this manner, the residue of the solvent may be reduced. Therefore, the polysilazane compound may have enough time to transform into the SiO₂ film during the transition phase, so that the product of dielectric film is less likely to have void defect (i.e., cavity) exists for the dielectric film when the SOD process is fulfilled. In addition, the mechanical strength of the product of dielectric film can be enhanced. In order to demonstrate the result, several “single stage baking” and “multi stage baking” experiments are carried out and then their results are compared, based on the shrinkage rate of the product of dielectric film. As shown in FIG. 4A, the SOD film of conventional “single stage baking” has a shrinkage rate of approximately 15.9˜16.4%. In comparison to the “multi stage baking” of the present invention, the shrinkage rate of the SOD film reaches approximately 17.1˜18.1%. Thus, it is revealed that the multi stage baking of the present invention may diminish the void defect significantly, with the shrinkage rate increasing by nearly 2%. Besides, the Reflective Index (RI) is also utilized to determine the quality of the SOD film. As shown in FIG. 4B, the RI value of the SOD film obtained through traditional “single stage baking” is around 1.449˜51.45; however, the RI value of the SOD film obtained through “multi stage baking” of the present invention is 1.4488˜1.4498. Thus, it is shown that the quality of the SOD film after “multi stage baking” has better performance.

Based on the foregoing, by modifying the baking process for the SOD method as disclosed by the present invention, more solvent is removed from the deposited film to reduce the amount of residue. From a physical standpoint, the conventional “single stage baking” would cause the polymer to quickly solidify. The solidification prevents the removal of the solvent at the bottom portion of the trench 12. However, through the improved SOD method of the present invention, particularly the multi stage heating process, the polymer solidifies more slowly in enabling the solvent to be released from the trench 12. The greater the aspect ratio is for the trench, the better is the improved effect.

The descriptions illustrated supra set forth simply the embodiment of the instant disclosure; however, the characteristics of the instant disclosure are by no means restricted thereto. All changes, alternations, or modifications conveniently considered by those skilled in the art are deemed to be encompassed within the scope of the instant disclosure delineated by the following claims.

What is claimed is:

1. A Spin-On Dielectric (SOD) method with multi stage ramping temperature for coating a dielectric material onto a substrate, comprising the steps of:
(a) placing the substrate on a chill plate to decrease the temperature;
(b) fixing the chilled substrate on a spinning device;
(c) turning on the spinning device for rotating the substrate;
(d) injecting the dielectric material onto the center of the substrate;
(e) spreading the dielectric material on the upper surface of the substrate by the rotation of the substrate;
(f) baking the substrate and the dielectric material by a heat plate to achieve multi stages ramping temperature, wherein the temperature of each stage has a steady state for a predetermined time and the posterior stage has higher temperature than the anterior stage;
(g) placing the substrate on the chill plate for cooling down;
(h) spreading a film of dielectric material and finishing the coating.

2. The SOD method with multi stage ramping temperature according to claim 1, wherein the dielectric material is polystyrene or polysilazane.

3. The SOD method with multi stage ramping temperature according to claim 2, wherein the average molecular weight of the dielectric material is 1,200˜20,000.

4. The SOD method with multi stage ramping temperature according to claim 1, wherein an upper surface of the substrate has at least one trench formed thereon, and wherein the trench has a width smaller than or equal to 0.2 μm and an aspect ratio greater than or equal to 2.

5. The SOD method with multi stage ramping temperature according to claim 1, wherein the step (f) has 2˜6 stages, and the temperature of each stage is kept in constant.

6. The SOD method with multi stage ramping temperature according to claim 5, wherein the temperatures of two adjacent stages define a temperature difference and the temperature differences between all stages are equal.

7. The SOD method with multi stage ramping temperature according to claim 6, wherein the step (f) has three stages, wherein for the first stage, the substrate and the dielectric material are heated at a constant temperature of 90° C.±10%, wherein for the second stage, the substrate and the dielectric material are heated at a constant temperature of 120° C.±10%, and wherein for the third stage, the substrate and the dielectric material are heated at a constant temperature at 150° C.±10%.

8. The SOD method with multi stage ramping temperature according to claim 1, wherein the step (f) has 2˜6 stages, and the temperature of each stage is increasing continuously.

9. The SOD method with multi stage ramping temperature according to claim 8, wherein each stage increases the temperature by a constant rate until a threshold temperature is reached.

10. The SOD method with multi stage ramping temperature according to claim 1, wherein total time of step (f) for heating is 3˜6 minutes.
